(19) United States
(12) Patent Application Publication
(10) Pub. No.: US 2025/0258217 A1
(43) Pub. Date: Aug. 14, 2025

(54) INTEGRATED CIRCUIT AND TEST SYSTEM INCLUDING THE SAME

(71) Applicant: SAMSUNG ELECTRONICS CO., LTD., SUWON-SI (KR)

(72) Inventors: Jehyun PARK, Suwon-si (KR); Taehong JANG, Suwon-si (KR); Hyunmin KYUNG, Suwon-si (KR); Sungcheol PARK, Suwon-si (KR); Jeongseok LEE, Suwon-si (KR)

(21) Appl. No.: 18/958,173

(22) Filed: Nov. 25, 2024

(30) Foreign Application Priority Data
Feb. 14, 2024 (KR) 10-2024-0021271
Apr. 3, 2024 (KR) 10 2024 0045511

(51) Int. Cl. G01R 31/28

(52) U.S. Cl. CPC G01R 31/2879; G01R 31/2863; G01R 31/287

(57) ABSTRACT

An integrated circuit and a test system including the same are provided. Provided is an integrated circuit including a plurality of first semiconductor intellectual property (IP) cores, a chip connection circuit including a first through silicon via, a second through silicon via, a receiver electrically connected to the first through silicon via, and a driver electrically connected to the second through silicon via, a multiplexing circuit configured to select an input/output (I/O) target selection signal, a test enable circuit configured to provide a test enable signal to the chip connection circuit, based on a test mode of the integrated circuit, and a test control circuit configured to provide the I/O target selection signal to the multiplexing circuit.

### CROSS-REFERENCE TO RELATED APPLICATIONS

This application claims priority under 35 U.S.C. § 119 to Korean Patent Application Nos. 10-2024-0021271, filed on Feb. 14, 2024, and 10-2024-0045511, filed on Apr. 3, 2024, in the Korean Intellectual Property Office, the disclosures of which are incorporated by reference herein in their entireties.

### FIELD

The present disclosure relates to an electronic device, and more particularly, to an integrated circuit and a test system including the same.

### DISCUSSION

A three-dimensional integrated circuit (3D IC) is an integrated circuit made by vertically stacking electronic components in a chip. This technology may maximize space utilization and improve chip performance by vertically stacking multiple layers of silicon wafers or dies and electrically connecting each layer, thereby meeting the demand for rapidly increasing high-performance chips.

Since each chip is vertically connected in a 3D IC, when designing a 3D IC, the 3D IC should be designed in consideration of the characteristics of the I/O circuit of each chip and circuits connected to the I/O circuit. If these characteristics are not considered, issues with increasing chip size and/or design complexity may occur.

### SUMMARY

The present disclosure provides an integrated circuit configured to minimize the area occupied by circuits constituting a 3D IC, and a test system including the same.

Technical aspects and embodiments of the inventive concept are not limited to those described supra. These and other technical aspects and embodiments may be clearly understood by a person ordinarily skilled in the pertinent field of art based on the following descriptions.

According to an embodiment of the inventive concept, there is provided an integrated circuit including a plurality of first semiconductor intellectual property (IP) cores, a chip connection circuit including a first through silicon via, a second through silicon via, a receiver electrically connected to the first through silicon via, and a driver electrically connected to the second through silicon via, a multiplexing circuit configured to select any one of the plurality of first semiconductor IP cores or the chip connection circuit as an input/output (I/O) target, based on an I/O target selection signal, a test enable circuit configured to provide a test enable signal to the chip connection circuit, based on a test mode of the integrated circuit, and a test control circuit configured to provide the I/O target selection signal to the multiplexing circuit.

According to an embodiment of the inventive concept, there is provided an integrated circuit including a first chip and a second chip, wherein the first chip includes a plurality of first semiconductor IP cores, a chip connection circuit including a first through silicon via and a second through silicon via electrically connected to the second chip, a first multiplexing circuit configured to select any one of the plurality of first semiconductor IP cores or the chip connection circuit as a first I/O target based on a first I/O target selection signal, a test enable circuit configured to provide a test enable signal to the chip connection circuit, based on a test mode of the integrated circuit, and a first test control circuit configured to provide the first I/O target selection signal to the first multiplexing circuit, and the second chip is arranged above the first chip, and includes a plurality of second semiconductor IP cores, a second multiplexing circuit configured to select any one of the plurality of second semiconductor IP cores as a second I/O target based on a second I/O target selection signal, and a second test control circuit configured to provide the second I/O target selection signal to the second multiplexing circuit.

According to an embodiment of the inventive concept, there is provided a test system including an integrated circuit, and test equipment configured to test the integrated circuit, wherein the integrated circuit includes a plurality of first semiconductor IP cores, a chip connection circuit including a first through silicon via, a second through silicon via, a receiver electrically connected to the first through silicon via, and a driver electrically connected to the second through silicon via, a first multiplexing circuit configured to select any one of the plurality of first semiconductor IP cores or the chip connection circuit as a first I/O target based on a first I/O target selection signal, a test enable circuit configured to provide a test enable signal to the chip connection circuit, based on a test mode of the integrated circuit, a first test control circuit configured to provide the first I/O target selection signal to the first multiplexing circuit, and a first chip including a first I/O circuit configured to electrically connect the test equipment and the first multiplexing circuit, transmit signals from the test equipment to the first multiplexing circuit, and transmit signals from the first multiplexing circuit to the test equipment.

### BRIEF DESCRIPTION OF THE DRAWINGS

Embodiments of the inventive concept will be more clearly understood from the following detailed description taken in conjunction with the accompanying drawings, in which:

FIG. 1 is a block diagram for describing a test system according to an embodiment;

FIG. 2 is an isometric diagram for explaining a structure of the test system of FIG. 1;

FIG. 3 is a schematic diagram for describing an integrated circuit according to an embodiment;

FIG. 4 is a schematic diagram for describing a test enable circuit according to an embodiment;

FIG. 5 is a schematic diagram for describing an integrated circuit according to an embodiment;

FIG. 6 is a schematic diagram for describing an integrated circuit according to an embodiment;

FIG. 7 is a schematic diagram for describing a first chip according to an embodiment;

FIG. 8 is a schematic diagram for describing a first chip according to an embodiment;

FIG. 9 is a schematic diagram for describing an integrated circuit according to an embodiment;

FIG. 10 is a schematic diagram for describing an integrated circuit according to an embodiment; and

FIG. 11 is a block diagram illustrating a system including an integrated circuit according to an embodiment.

### DETAILED DESCRIPTION

Hereinafter, embodiments will be described in detail with reference to the accompanying drawings. When described with reference to the drawings, the same, similar or corresponding components may be assigned with the like reference numerals, and redundant descriptions thereof may be omitted.

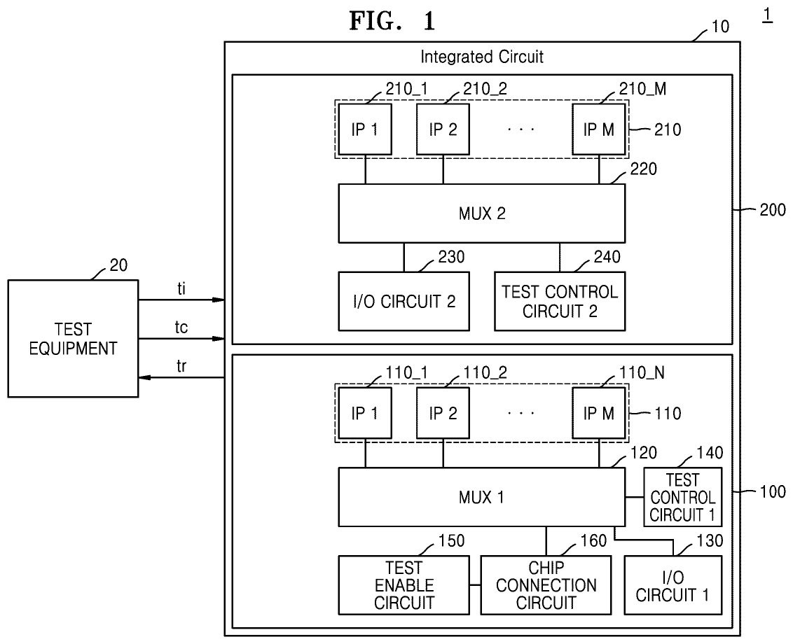

FIG. 1 illustrates a test system 1 according to an embodiment.

Referring to FIG. 1, the test system 1 may include an integrated circuit 10 and test equipment 20.

The test equipment 20 may be any device suitable for testing the integrated circuit 10. The test equipment 20 may transmit specific signals to the integrated circuit 10 and may receive specific signals from the integrated circuit 10. The specific signals may include, for example, a test input signal ti transmitted by the test equipment 20 to the integrated circuit 10, a test control signal tc for controlling circuits related to tests provided in the integrated circuit 10, and a test result signal tr transmitted by the integrated circuit 10 to the test equipment 20. In this case, the test input signal ti may include test patterns used to test the integrated circuit 10. The test result signal tr may include test result values corresponding to the test input signal ti.

In an embodiment, the test equipment 20 is a computer system, such as for example, a personal computer or the like, and may include a debugging program for testing.

In an embodiment, the test equipment 20 may be referred to as automated test equipment (ATE).

In an embodiment, the test equipment 20 may test the integrated circuit 10. In this disclosure, testing the integrated circuit 10 by the test equipment 20 may mean testing a test target by using at least one of a plurality of semiconductor intellectual property (IP) cores provided in the integrated circuit 10 as the test target.

In an embodiment, the test equipment 20 may perform a test on each chip in a state in which the second chip 200 is not arranged above the first chip 100, that is, in a state in which each chip is present by itself.

The integrated circuit 10 may include the first chip 100 and the second chip 200. The second chip 200 may be arranged above the first chip 100. In the present disclosure, the first chip 100 may be referred to as a lower chip, a lower integrated circuit, or a first integrated circuit, and the second chip 200 may be referred to as an upper chip, an upper integrated circuit, or a second integrated circuit.

In an embodiment, the integrated circuit 10 may be referred to as a three-dimensional integrated circuit (3D IC).

In an embodiment, the test equipment 20 may be electrically connected to a first input/output (I/O) circuit 130 through a bump. The bump may be a conductive bump. The conductive bump may include a metal such as tin (Sn), copper (Cu), silver (Ag), gold (Au), tungsten (W), bismuth (Bi), zirconium (Zr), zinc (Zn), cobalt (Co), nickel (Ni), or the like, or an alloy thereof, without limitation thereto.

The first chip 100 may include a plurality of first semiconductor IP cores 110, a first multiplexing circuit 120, a first I/O circuit 130, a first test control circuit 140, a test enable circuit 150, and a chip connection circuit 160.

The first chip 100 may be electrically connected to an external device through the first I/O circuit 130. The external device may be, for example, the test equipment 20. Hereinafter, for convenience of explanation, an external device will be described on the assumption that the external device is the test equipment 20. However, this is not intended to limit the inventive concept. The chip connection circuit 160 of the first chip 100 and a second I/O circuit 230 of the second chip 200 may be electrically connected with each other.

The plurality of first semiconductor IP cores 110 may include a first lower semiconductor IP core 110_1 to an N-th lower semiconductor IP core 110_N, where N is a natural number greater than one. For ease of description in the present disclosure, in order to distinguish and explain semiconductor IP cores included in the first chip 100 and semiconductor IP cores included in the second chip 200, each semiconductor IP core included in the first chip 100 may be referred to as a lower semiconductor IP core, and each semiconductor IP core included in the second chip 200 may be referred to as an upper semiconductor IP core, without limitation thereto.

As used herein, a semiconductor IP core or block may be a reusable unit of logic, cell, or integrated circuit layout design that may be the intellectual property of a party. In addition, in this disclosure, each semiconductor IP core may refer to a circuit, chip layout design, software code, and/or the like that may be reused while having independent functions. When designing a System on Chip (SoC) or Field Programmable Gate Array (FPGA) circuit, microprocessors, memories, digital signal processors, analog signal processors, various input/output (I/O) circuits, and the like may be used as functional blocks. For example, the types of semiconductor IP cores may include a soft IP core in the form of a register transfer level (RTL) code that may be logically synthesized, a hard IP core in the form of design data that is arranged and wired according to a predetermined process, a firmware IP core in the form of a gate-level netlist with some floor planning information, a device driver for driving a circuit, a standard cell, a macro block, a library of shared or standard software, firmware, or the like. Most semiconductor IP cores may be driven by register-based reads or register-based writes, may have deterministic characteristics having the same output for a given input, and may have a constant number of cycles taken to perform an operation, without limitation thereto.

The first multiplexing circuit 120 may select a first I/O target according to the control of the first test control circuit 140. Specifically, the first multiplexing circuit 120 may select the first I/O target based on the first I/O target selection signal received from the first test control circuit 140. In the present disclosure, the first I/O target may refer to any one selected from the plurality of semiconductor IP cores 110 or the chip connection circuit 160.

The first multiplexing circuit 120 may include a multiplexer and a demultiplexer. The first multiplexing circuit 120 may operate as a multiplexer by transmitting, to the first I/O circuit 130, a signal received from the first I/O target. In addition, the first multiplexing circuit 120 may operate as a demultiplexer by transmitting, to the first I/O target, a signal received from the test equipment 20 to the first I/O circuit 130. In an embodiment, the first multiplexing circuit 120 may be referred to as a first switching circuit.

The first I/O circuit 130 may transmit a signal received from the test equipment 20 to the first multiplexing circuit 120, and may transmit a signal received from the first multiplexing circuit 120 to the test equipment 20.

The first test control circuit 140 may generate a first I/O target selection signal. The first test control circuit 140 may provide the first I/O target selection signal to the first multiplexing circuit 120.

In an embodiment, the first test control circuit 140 may generate a first I/O target selection signal based on the test control signal tc received from the test equipment 20. For example, when the test equipment 20 is provisioned to test the first lower semiconductor IP core 110_1, the first I/O target selection signal may include information corresponding to the first lower semiconductor IP core 110_1.

The test enable circuit 150 may generate a test enable signal during an exclusive test operation associated with the first chip 100. Through the test enable signal, it is possible to prevent a decrease in reliability of the test result for the first chip 100 due to X-propagation by an X value. In the present disclosure, the X value may refer to a value corresponding to an undefined logical state. For example, the X value might be either a first value representing “1” or a second value representing “0”.

The second chip 200 may include a plurality of second semiconductor IP cores 210, a second multiplexing circuit 220, a second I/O circuit 230, and a second test control circuit 240.

The plurality of second semiconductor IP cores 210 may include a first upper semiconductor IP core 210_1 to an M-th upper semiconductor IP core 210_M, where M is a natural number greater than one.

The second multiplexing circuit 220 may include a multiplexer and a demultiplexer. Thus, the second multiplexing circuit 220 may operate as a multiplexer by transmitting, to the second I/O circuit 230, a signal received from the second I/O target. In addition, the second multiplexing circuit 220 may operate as a demultiplexer by transmitting, to the second I/O target, a signal received from the test equipment 20 to the second I/O circuit 230. In an embodiment, the second multiplexing circuit 220 may be referred to as a second switching circuit.

The second test control circuit 240 may generate a second I/O target selection signal. The second test control circuit 240 may provide the second I/O target selection signal to the second multiplexing circuit 220. In an embodiment, the second test control circuit 240 may generate a second I/O target selection signal based on the test control signal tc received from the test equipment 20. For example, when the test equipment 20 is provisioned to test the second upper semiconductor IP core 210_2, the second I/O target selection signal may include information corresponding to the second upper semiconductor IP core 210_2.

In an embodiment, the first chip 100 and the second chip 200 may each be a semiconductor chip formed on a separate wafer. The integrated circuit 10 may be manufactured by forming the first chip 100 and the second chip 200 on separate wafers, respectively, and then connecting the first chip 100 with the second chip 200. The test equipment 20 may independently perform a test on each chip before the first chip 100 and the second chip 200 are connected with each other. In this case, the test enable circuit 150 provided in the first chip 100 may prevent the X value from propagating to the components in the first chip 100 through the chip connection circuit 160 of the first chip 100 by generating the test enable signal. In addition, the test equipment 20 may perform a test on each chip even after the first chip 100 and the second chip 200 are connected with each other.

In an embodiment, the voltage of the signal transmitted and received through the first I/O circuit 130 may be the first voltage. The first voltage may be referred to as an I/O voltage. The first voltage may be a voltage required to provide a signal from the first chip 100 to the test equipment 20, or to transmit a signal from the test equipment 20 to the first chip 100. For example, the magnitude of the I/O voltage may be 1.8 V.

The voltage of the signal transmitted and received through the second I/O circuit 230 may be a second voltage. The second voltage may be referred to as a logic voltage, and the second voltage may be a voltage required to operate each component included in the second chip 200. The magnitude of the second voltage may be less than the magnitude of the first voltage. For example, the magnitude of the logic voltage may be 0.75 V. This is because the first voltage is a voltage corresponding to a signal transmitted and received between the test equipment 20 and the first chip 100, and thus the drive strength should be greater than the second voltage required by the internal components of each chip.

According to the above-described embodiment, by configuring the integrated circuit 10 so that the voltage of the signal transmitted and received between the first chip 100 and the second chip 200 through the second I/O circuit 230 becomes a second voltage other than the first voltage, a voltage level shifter for shifting the voltage level of the signal transmitted and received between the second chip 200 and the first chip 100 need not be included in the integrated circuit 10. That is, since the integrated circuit 10 does not include a voltage level shifter, the area of the integrated circuit 10 may be reduced.

In an embodiment, an integrated circuit may further include a third chip disposed on the second chip 200 and the first chip 100. The third chip may be substantially the same as described supra for the second chip 200, and duplicate description thereof may be omitted. In this embodiment, the second chip 200 may further include a second chip connection circuit coupled to a third I/O circuit of the third chip. In this case, the first I/O target may refer to any one selected from the plurality of first semiconductor IP cores 110 or the first chip connection circuit 160; the second I/O target may refer to any one selected from the plurality of second semiconductor IP cores 210 or the second chip connection circuit; and a third I/O target may refer to any one selected from a plurality of third semiconductor IP cores of the third chip.

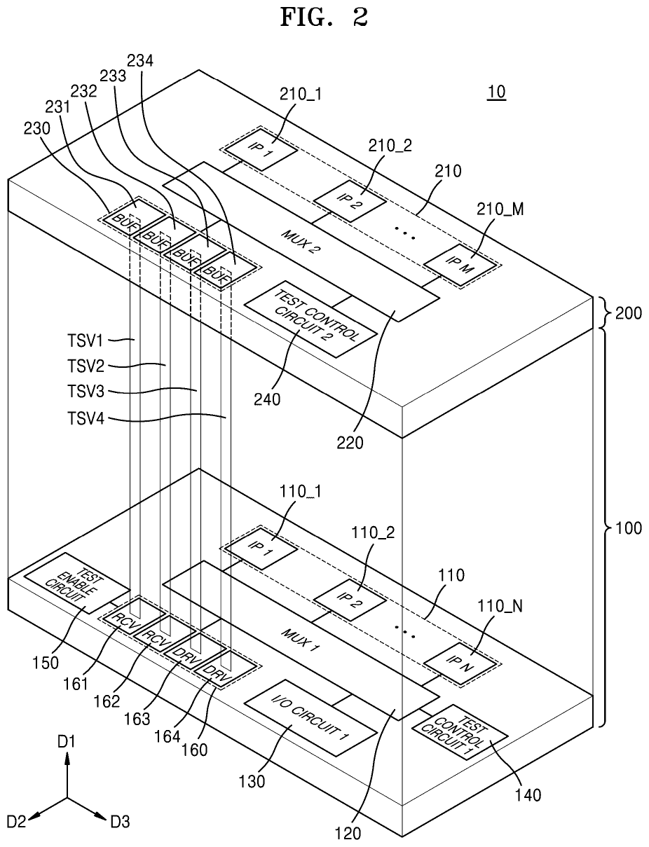

FIG. 2 illustrates a structure of the test system 1 of FIG. 1. FIG. 2 may be described with reference to FIG. 1, and redundant descriptions may be omitted.

Referring to FIG. 2, the second chip 200 may be arranged in a vertical direction of the first chip 100. In other words, the second chip 200 may be arranged above the first chip 100. In the present disclosure, a vertical direction is defined as a first direction D1, a second direction D2 is defined as a direction perpendicular to the first direction D1, and a third direction D3 is defined as a direction perpendicular to the first direction D1 and the second direction D2. In addition, the second direction D2 may be referred to as a first horizontal direction, and the third direction D3 may be referred to as a second horizontal direction.

The chip connection circuit 160 of the first chip 100 and the second I/O circuit 230 of the second chip 200 may be electrically connected with each other. The chip connection circuit 160 may include a first receiver 161, a second receiver 162, a first driver 163, a second driver 164, and first to fourth through silicon vias TSV1 to TSV4.

The first to fourth through silicon vias TSV1 to TSV4 may be arranged to penetrate the first chip 100 in the first direction D1. The first receiver 161 may be electrically connected to the first through silicon via TSV1. The second receiver 162 may be electrically connected to the second through silicon via TSV2. The first driver 163 may be electrically connected to the third through silicon via TSV3. The second driver 164 may be electrically connected to the fourth through silicon via TSV4. In FIG. 2, four through silicon vias TSV1 to TSV4 are illustrated as examples for description, and are not intended to limit the inventive concept. Likewise, illustrating the four I/O buffers 231 to 234 is for illustration and not for limiting the inventive concept. In addition, illustrating two receivers 161 and 162 and two drivers 163 and 164 is for illustration and not for limiting the inventive concept.

The second I/O circuit 230 may include a first I/O buffer 231, a second I/O buffer 232, a third I/O buffer 233, and a fourth I/O buffer 234.

The first I/O buffer 231 may be electrically connected to the first through silicon via TSV1. The second I/O buffer 232 may be electrically connected to the second through silicon via TSV2. The third I/O buffer 233 may be electrically connected to the third through silicon via TSV3. The fourth I/O buffer 234 may be electrically connected to the fourth through silicon via TSV4.

In an embodiment, bumps may be arranged between the first to fourth through silicon vias TSV1 to TSV4 and the first to fourth I/O buffers 231 to 234.

In an embodiment, the first to fourth I/O buffers 231 to 234 may be I/O buffers that transmit signals in a unilateral manner. For example, the first I/O buffer 231 may transmit a signal to the first receiver 161 through the first through silicon via TSV1. The second I/O buffer 232 may transmit a signal to the second receiver 162 through the second through silicon via TSV2. The third I/O buffer 233 may receive a signal from the first driver 163 through the third through silicon via TSV3. The fourth I/O buffer 234 may receive a signal from the second driver 164 through the fourth through silicon via TSV4.

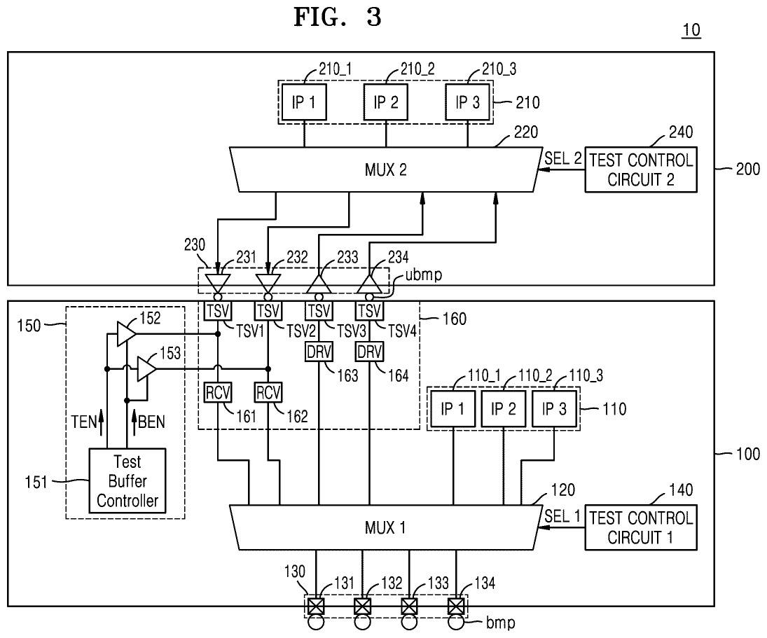

FIG. 3 illustrates an integrated circuit 10 according to an embodiment. FIG. 3 may be described with reference to FIGS. 1 and 2, and redundant descriptions may be omitted.

Since the feature in which the first to fourth through silicon vias TSV1 to TSV4 are arranged to penetrate the first chip 100 in the first direction D1 is described with reference to FIG. 2, for convenience of description with reference to FIG. 3 and the subsequent drawings, the electrical connections between the first to fourth through silicon vias TSV1 to TSV4 and other components is to be described with reference to FIG. 3.

In an embodiment, the integrated circuit 10 may operate in three modes. When the integrated circuit 10 operates in a normal mode, it may mean that the integrated circuit 10 operates in a user mode without performing a test operation.

When the integrated circuit 10 operates in a first test mode, it may be premised on a state in which the first chip 100 and the second chip 200 have yet to be connected with each other. In other words, only a single chip of either the first chip 100 or the second chip 200 may be included in the integrated circuit 10 during the first test mode. For example, when a test is performed on the first chip 100 before the first chip 100 and the second chip 200 are connected with each other, the integrated circuit 10 including the first chip 100 may operate in the first test mode. Likewise, when a test is performed on the second chip 200 before the first chip 100 and the second chip 200 are connected with each other, the integrated circuit 10 including the second chip 200 may operate in the first test mode.

When the integrated circuit 10 operates in a second test mode, it may be premised on a state in which the first chip 100 and the second chip 200 have been connected with each other. In other words, when the integrated circuit 10 operates in a second test mode, it may be in a state in which both the first chip 100 and the second chip 200 may be included in the integrated circuit 10.

The plurality of first semiconductor IP cores 110 may include a first lower semiconductor IP core 110_1, a second lower semiconductor IP core 110_2, and a third lower semiconductor IP core 110_3. The fact that the plurality of first semiconductor IP cores 110 includes three semiconductor IP cores is an example for explanation purposes, and of course, fewer or more semiconductor IP cores may be included without limitation.

The first multiplexing circuit 120 may operate under the control of the first test control circuit 140. The first multiplexing circuit 120 may select any one of the plurality of first semiconductor IP cores 110 or the chip connection circuit 160 as the first I/O target based on a first I/O selection signal SEL1 received from the first test control circuit 140.

The first multiplexing circuit 120 may provide, to the first I/O target, a signal transmitted from the first I/O circuit 130. In addition, the first multiplexing circuit 120 may provide, to the first I/O circuit 130, a signal received from the first I/O target.

In an embodiment, when the first I/O target is the first lower semiconductor IP core 110_1, the first multiplexing circuit 120 may transmit, to the first I/O circuit 130, a signal received from the first lower semiconductor IP core 110_1. In addition, the first multiplexing circuit 120 may transmit, to the first I/O target, a signal received from the first I/O circuit 130.

In an embodiment, when the first I/O target is the chip connection circuit 160, the first multiplexing circuit 120 may transmit, to the first I/O circuit 130, a signal received from the chip connection circuit 160. In addition, the first multiplexing circuit 120 may transmit, to the first I/O target, a signal received from the first I/O circuit 130.

The first chip 100 may receive a signal from the test equipment 20 through the first I/O circuit 130 and provide a signal to the test equipment 20 through the first I/O circuit 130. The first I/O circuit 130 may include first to fourth I/O buffers 131 to 134. Unlike the first to fourth I/O buffers 231 to 234 provided in the second chip 200, the first to fourth I/O buffers 131 to 134 may be bilateral buffers. For example, the first I/O buffer 131 may receive a signal from the test equipment 20, and may provide a signal generated by the integrated circuit 10 to the test equipment 20. The first I/O circuit 130 may be electrically connected to an external device, such as the test equipment 20 of FIG. 1, through first or lower bumps bmp. A voltage of a signal transmitted and received between the first I/O circuit 130 and an external device may be a first voltage such as an I/O voltage. A voltage of a signal transmitted and received between the first I/O circuit 130 and the first multiplexing circuit 120 may be a second voltage such as a logic voltage.

The first test control circuit 140 may generate a first I/O target selection signal SEL1.

In an embodiment, the first test control circuit 140 may generate the first I/O target selection signal SEL1 based on the test control signal tc received from the test equipment 20.

In an embodiment, the test equipment 20 and the first test control circuit 140 may be electrically connected with each other through separate test I/O terminals.

In an embodiment, it may be assumed for ease of explanation, without limitation thereto, that the first lower semiconductor IP core 110_1 is a test target. The first test control circuit 140 may generate a first I/O target selection signal SEL1 including information corresponding to the first lower semiconductor IP core 110_1.

In an embodiment, it may be assumed for ease of explanation, without limitation thereto, that the second upper semiconductor IP core 210_2 is a test target. The first test control circuit 140 may generate a first I/O target selection signal SEL1 including information corresponding to the chip connection circuit 160.

The test enable circuit 150 may include a test buffer controller 151, a first test buffer 152, and a second test buffer 153. The test buffer controller 151 may generate a test enable signal TEN and a buffer enable signal BEN.

In an embodiment, the test buffer controller 151 may generate the test enable signal TEN and the buffer enable signal BEN based on the test control signal tc received from the test equipment 20.

The first test buffer 152 and the second test buffer 153 may receive the test enable signal TEN and the buffer enable signal BEN from the test buffer controller 151. The first test buffer 152 and the second test buffer 153 may provide the test enable signal TEN to the chip connection circuit 160 in response to the buffer enable signal BEN. The first test buffer 152 and the second test buffer 153 may be a tri-state buffer. For example, when the logic level of the buffer enable signal BEN is a low level, the first test buffer 152 and the second test buffer 153 may be in a high-impedance state. When the first test buffer 152 and the second test buffer 153 are in a high-impedance state, the signal generated by the test enable circuit 150 need not be provided to the chip connection circuit 160. For example, when the logic level of the buffer enable signal is a high level, the first test buffer 152 and the second test buffer 153 may provide the test enable signal TEN to the chip connection circuit 160.

In an embodiment, the states of the first test buffer 152 and the second test buffer 153 may be determined according to the operation modes of the integrated circuit 10. When the operation mode of the integrated circuit 10 is in the first test mode, the logic level of the buffer enable signal BEN may be a high level. The first test buffer 152 and the second test buffer 153 may provide the test enable signal TEN to the chip connection circuit 160 in response to the logic level of the buffer enable signal BEN being the high level. When the operation mode of the integrated circuit 10 is in the second test mode or the normal mode, the logic level of the buffer enable signal BEN may be a low level. The first test buffer 152 and the second test buffer 153 may operate in a high-impedance state in response to the logic level of the buffer enable signal BEN being the low level.

The operation mode of the integrated circuit 10 being the first test mode may assume that the first chip 100 and the second chip 200 are not yet connected with each other, and may be a test mode set when the second chip 200 is not included in the integrated circuit 10, without limitation thereto.

The operation mode of the integrated circuit 10 being the second test mode may assume that the first chip 100 and the second chip 200 are connected with each other, and may be a test mode set when the integrated circuit 10 includes the first chip 100 and the second chip 200, without limitation thereto.

The fact that the operation mode of the integrated circuit 10 is a normal mode may mean a mode set when the integrated circuit 10 does not perform a test operation, but performs a normal operation in an environment other than a test environment, and may assume that the first chip 100 and the second chip 200 are connected with each other, without limitation thereto.

In an embodiment, each of the first test buffer 152 and the second test buffer 153 may be implemented using a multiplexer.

In an embodiment, the test equipment 20 and the test enable circuit 150 may be electrically connected with each other through separate test I/O terminals.

The chip connection circuit 160 may include the first to fourth through silicon vias TSV1 to TSV4, the first receiver 161, the second receiver 162, the first driver 163, and the second driver 164. The chip connection circuit 160 may be electrically connected to the second I/O circuit 230 of the second chip 200 through second or upper bumps ubmp. The size of each of the second bumps ubmp may be smaller than the size of each of the first bumps bmp. In an embodiment, the second bumps ubmp may be referred to as micro-bumps.

The second I/O circuit 230 may include the first to fourth I/O buffers 231 to 234. The first I/O buffer 231 and the second I/O buffer 232 may provide, to the chip connection circuit 160, a signal received from the second multiplexing circuit 220. The third I/O buffer 233 and the fourth I/O buffer 234 may provide, to the second multiplexing circuit 220, a signal received from the chip connection circuit 160. The voltage of the signal transmitted and received between the second I/O circuit 230 and the second multiplexing circuit 220 may be a second voltage such as a logic voltage. The voltage of a signal transmitted and received between the second I/O circuit 230 and the chip connection circuit 160 may also be the second voltage.

Unlike the first I/O circuit 130, in the case of the second I/O circuit 230, since the voltage of the signal transmitted and received through the second I/O circuit 230 is the same as the second voltage, a level shifter for shifting the first voltage to the second voltage need not be required in the first chip 100.

The plurality of second semiconductor IP cores 210 may include a first upper semiconductor IP core 210_1, a second upper semiconductor IP core 210_2, and a third upper semiconductor IP core 210_3. The fact that the plurality of second semiconductor IP cores 210 includes three semiconductor IP cores is an example for explanation purposes, and of course, fewer or more semiconductor IP cores may be included.

The second multiplexing circuit 220 may operate under the control of the second test control circuit 240. The second multiplexing circuit 220 may select any one of the plurality of second semiconductor IP cores 210 as the second I/O target based on a second I/O selection signal SEL2 received from the second test control circuit 240.

The second multiplexing circuit 220 may provide, to the second I/O target, a signal transmitted from the second I/O circuit 230. In addition, the second multiplexing circuit 220 may provide, to the second I/O circuit 230, a signal received from the second I/O target.

In an embodiment, when the second I/O target is the first upper semiconductor IP core 210_1, the second multiplexing circuit 220 may transmit, to the second I/O circuit 230, a signal received from the first upper semiconductor IP core 210_1. In addition, the second multiplexing circuit 220 may transmit, to the second I/O target, a signal received from the second I/O circuit 230.

The second test control circuit 240 may generate a second I/O target selection signal SEL2.

In an embodiment, the second test control circuit 240 may generate the second I/O target selection signal SEL2 based on the test control signal to received from the test equipment 20.

In an embodiment, the test equipment 20 and the second test control circuit 240 may be electrically connected with each other through separate test I/O terminals.

In an embodiment, it may be assumed for ease of explanation, without limitation thereto, that the first lower semiconductor IP core 110_1 is a test target. When the first lower semiconductor IP core 110_1 is a test target, since a signal transmitted and received through the chip connection circuit 160, such as a signal between the first chip 100 and the second chip 200, is blocked by the first multiplexing circuit 120, the second test control circuit 240 need not generate the second I/O target selection signal SEL2. Alternatively, even if the second test control circuit 240 generates the second I/O target selection signal SEL2 including an arbitrary value, the value need not affect the integrated circuit 10 performing a test operation on the first lower semiconductor IP core 110_1.

In an embodiment, it may be assumed for ease of explanation, without limitation thereto, that the second upper semiconductor IP core 210_2 is a test target. In this case, the second test control circuit 240 may generate a second I/O target selection signal SEL2 including information corresponding to the second upper semiconductor IP core 210_2.

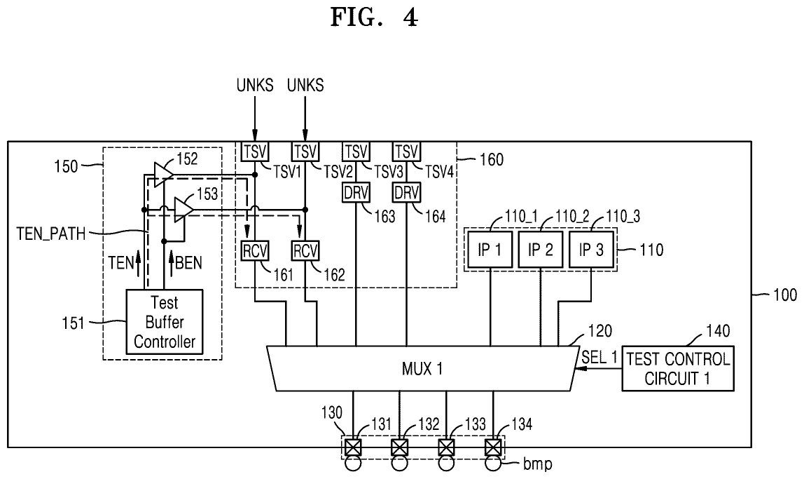

FIG. 4 illustrates a test enable circuit 150 according to an embodiment. FIG. 4 may be described with reference to FIGS. 1 to 3, and redundant description may be omitted.

In FIG. 4, it may be assumed for ease of explanation, without limitation thereto, that the first chip 100 is tested through the test equipment 20 in a state before the first chip 100 and the second chip 200 are connected with each other. As shown in FIG. 4, even before the first chip 100 and the second chip 200 are connected with each other, each chip may be tested through the test equipment 20 such as in the process of producing each chip. In this case, one-side ends of the first to fourth through silicon vias TSV1 to TSV4 are electrically connected to the first receiver 161, the second receiver 162, the first driver 163, and the second driver 164, respectively; but the other-side ends of the first to fourth through silicon vias TSV1 to TSV4 need not be electrically connected at all. Through the first through silicon via TSV1 and the second through silicon via TSV2, unknown signals UNKS1 and UNKS2 may flow into the chip connection circuit 160 regardless of the user's intention to test the first chip 100. When the unknown signals UNKS1 and UNKS2 flow into the chip connection circuit 160, unexpected issues may occur in components included in the first chip 100. In this case, the unknown signals UNKS1 and UNKS2 may mean signals in a state where it is unknown whether the value to be expressed is “1” or “0”. In an embodiment, a value represented by the unknown signal UNKS1 or UNKS2 may be referred to as an X value. In addition, unexpected issues caused by unknown signals UNKS1 and/or UNKS2 may be referred to as X-propagation issues. Due to the X-propagation issues caused by the unknown signals UNKS1 and UNKS2, unintended values may be introduced for the semiconductor IP cores selected as test targets, thereby reducing the accuracy of the test results. Accordingly, the first chip 100 according to an embodiment may improve the accuracy of the test result for the first chip 100 by solving the X-propagation issues caused by the unknown signals UNKS1 and UNKS2 by applying the test enable circuit 150.

Referring to FIG. 4, the integrated circuit 10 may include the first chip 100. The first chip 100 need not be electrically connected to the second chip 200, but may be connected to the test equipment 20 alone. Therefore, when only the first chip 100 is connected to the test equipment 20 alone as shown in FIG. 4, the operation mode of the integrated circuit 10 may be the first test mode. In this disclosure, setting the operation mode of the integrated circuit 10 to the first test mode may mean setting the operation mode of the chip connected to the test equipment 20, such as the first chip 100 of FIG. 4, to the first test mode when the integrated circuit 10 includes only one chip.

When the integrated circuit 10 operates in the first test mode, the test enable circuit 150 may generate a buffer enable signal BEN and a test enable signal TEN. In this case, logic levels of the buffer enable signal BEN and the test enable signal TEN may be logic high levels.

In response to the logic level of the buffer enable signal BEN being a high level, the first test buffer 152 may provide, to the first receiver 161, the test enable signal TEN received from the test buffer controller 151. Likewise, in response to the logic level of the buffer enable signal BEN being the high level, the second test buffer 153 may provide, to the second receiver 162, the test enable signal TEN received from the test buffer controller 151. The test enable signal TEN may be transmitted from the test buffer 152 to the first receiver 161 and the second receiver 162 along test enable signal paths TEN_PATH shown by dashed arrow lines.

The logic levels of the buffer enable signal BEN and the test enable signal TEN are high levels for illustration and are not intended to limit the inventive concept. For example, in response to the logic level of the buffer enable signal BEN being a low level, the first test buffer 152 and the second test buffer 153 may configure the first chip 100 to provide the test enable signal TEN to the first receiver 161 and the second receiver 162.

In an embodiment, the test enable signal TEN may be a signal including a first value. That is, instead of the unknown signals UNKS1 and UNKS2 flowing into the first receiver 161 and the second receiver 162, the test enable signal TEN, which is a signal that definitively provides the first value, may be provided to the first receiver 161 and the second receiver 162. In the present disclosure, the first value may mean “1”, and the second value may mean “0”.

Since the value received by the first multiplexing circuit 120 through the first receiver 161 and the second receiver 162 is the first value, it is possible to prevent an unintended value from flowing into the first chip 100 due to the unknown signals UNKS1 and UNKS2 during the test, and thus the accuracy of the test for the first chip 100 may be improved. However, the fact that the test enable signal TEN represents the first value is for illustration and is not intended to limit the inventive concept. The test enable signal TEN may be a signal indicating the second value.

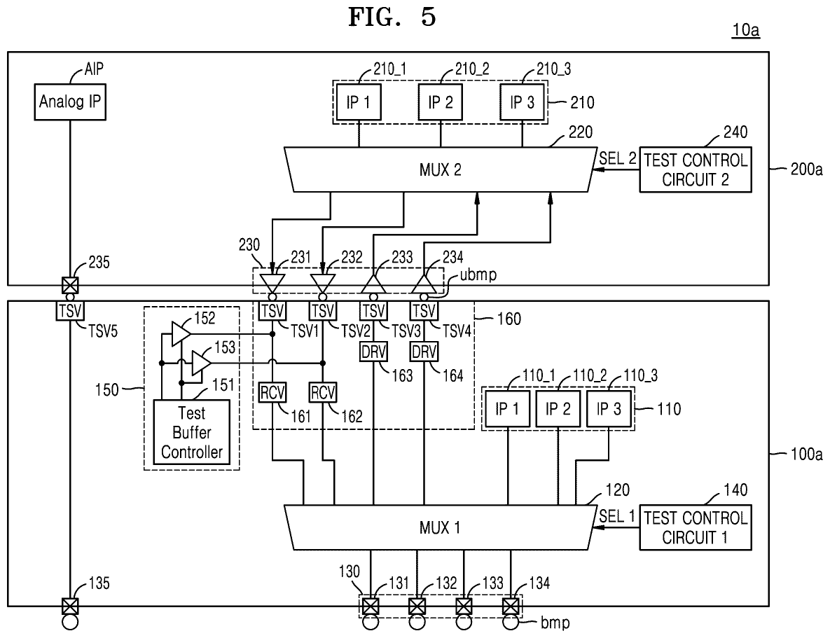

FIG. 5 illustrates an integrated circuit 10a according to an embodiment. FIG. 5 may be described with reference to FIGS. 1 to 4, and redundant descriptions may be omitted.

Referring to FIG. 5, the integrated circuit 10a of FIG. 5 may correspond to the integrated circuit 10 of FIG. 3. Unlike the second chip 200 of FIG. 3, a second chip 200a of FIG. 5 may further include an analog semiconductor IP (AIP) core and a fifth I/O buffer 235. Unlike the first chip 100a of FIG. 3, a first chip 100a of FIG. 5 may further include a fifth I/O buffer 135 and a fifth through silicon via TSV5.

The AIP core may provide an analog signal to the first chip 100a through the fifth I/O buffer 235 of the second chip 200a. The first chip 100a may provide an analog signal received from the AIP core to an external device through the fifth through silicon via TSV5 and the fifth I/O buffer 135.

Since the fifth through silicon via TSV5 transmits an analog signal, unlike the first to fourth through silicon vias TSV1 to TSV4, a receiver or driver need not be required.

In an embodiment, the AIP core may include an analog-to-digital converter, a digital-to-analog converter, a voltage regulator, a phase-locked loop, and the like.

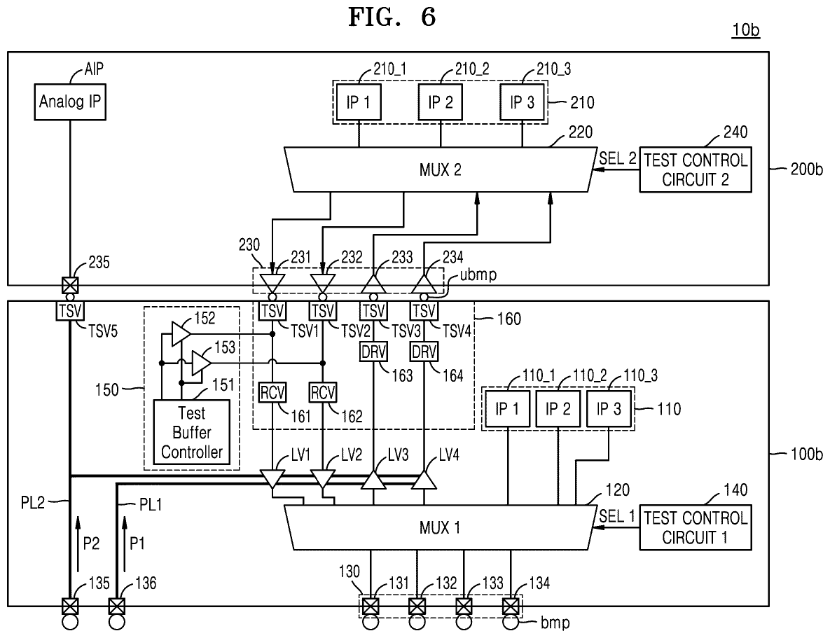

FIG. 6 illustrates an integrated circuit 10b according to an embodiment. FIG. 6 may be described with reference to FIGS. 1 to 5, and redundant descriptions may be omitted.

In FIG. 6, it may be assumed for ease of explanation, without limitation thereto, that voltages of signals transmitted and received through the first I/O circuit 130 are I/O voltages. In addition, it may be assumed for ease of explanation, without limitation thereto, that logic voltages required to operate components of a first chip 100b are first logic voltages, and logic voltages required to operate components of a second chip 200b are second logic voltages. In this case, it may be assumed for ease of explanation, without limitation thereto, that the first logic voltages are different from the second logic voltages. In this case, as shown in FIG. 6, by providing first to fourth level shift circuits LV1 to LV4 in the first chip 100b, a logic voltage required by each of the first chip 100b and the second chip 200b may be provided to each chip.

Referring to FIG. 6, the integrated circuit 10b of FIG. 6 may correspond to the integrated circuit 10a of FIG. 5, and duplicate description may be omitted. However, unlike the first chip 100a of FIG. 5, the first chip 100b of FIG. 6 may further include a first power line PL1, a second power line PL2, and the first to fourth level shift circuits LV1 to LV4.

The first to fourth level shift circuits LV1 to LV4 may be connected to the first power line PL1 and the second power line PL2. The first level shift circuit LV1 may be electrically connected between a first multiplexing circuit 120 and a first receiver 161. The second level shift circuit LV2 may be electrically connected between the first multiplexing circuit 120 and a second receiver 162. The third level shift circuit LV3 may be electrically connected between the first multiplexing circuit 120 and a first driver 163. The fourth level shift circuit LV4 may be electrically connected between the first multiplexing circuit 120 and a second driver 164.

The first chip 100b may receive a first power P1 and a second power P2 from an external device. A voltage of the first power P1 may correspond to the first logic voltage, and a voltage of the second power P2 may correspond to the second logic voltage. The first chip 100b may receive the first power P1 through the first power line PL1. The first chip 100b may receive the second power P2 through the second power line PL2.

The first I/O circuit 130 may receive a signal having an I/O voltage from the outside, convert the voltage of the received signal into the first logic voltage, and provide the converted first logic voltage to the first multiplexing circuit 120. Likewise, the first I/O circuit 130 may receive a signal having the first logic voltage from the first multiplexing circuit 120, convert the voltage of the received signal into an I/O voltage, and provide the I/O voltage to an external device.

The first level shift circuit LV1 may receive a signal having the second logic voltage from the first receiver 161, shift the voltage of the received signal to the first logic voltage, and provide the first logic voltage to the first multiplexing circuit 120.

The second level shift circuit LV2 may receive a signal having the second logic voltage from the second receiver 162, shift the voltage of the received signal to the first logic voltage, and provide the first logic voltage to the first multiplexing circuit 120.

The third level shift circuit LV3 may receive a signal having the first logic voltage from the first multiplexing circuit 120, shift the voltage of the received signal to the second logic voltage, and provide the second logic voltage to the first driver 163.

The fourth level shift circuit LV4 may receive a signal having the first logic voltage from the first multiplexing circuit 120, shift the voltage of the received signal to the second logic voltage, and provide the second logic voltage to the second driver 164.

In an embodiment, the second power line PL2 may be electrically connected to the fifth through silicon via TSV5. The second power P2 supplied through the second power line PL2 may be provided to the AIP core through the fifth through silicon via TSV5 and the fifth I/O buffer 235.

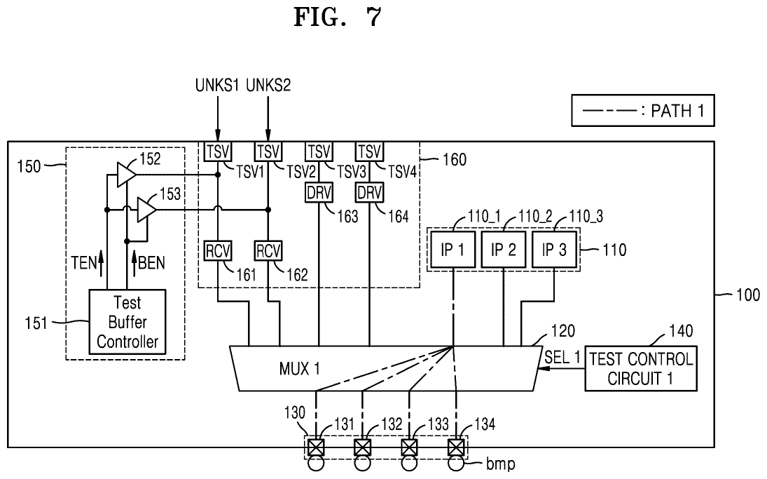

FIG. 7 illustrates a first chip 100 according to an embodiment. FIG. 7 may be described with reference to FIGS. 1 to 4, and redundant descriptions may be omitted.

Specifically, FIG. 7 shows a case in which the first chip 100 operates in a first test mode. The fact that the first chip 100 operates in the first test mode may be premised that the first chip 100 and the second chip 200 are not connected with each other. In FIG. 7, it may be assumed for ease of explanation, without limitation thereto, that a test target of the test equipment 20 is a first lower semiconductor IP core 110_1.

The test equipment 20 may control the first test control circuit 140 and the test enable circuit 150 so that the first chip 100 operates in the first test mode.

The test equipment 20 may control the first test control circuit 140 so that the first test control circuit 140 generates a first I/O selection signal SEL1 including information corresponding to the first lower semiconductor IP core 110_1.

The first multiplexing circuit 120 may select the first lower semiconductor IP core 110_1 as an I/O target in response to the first I/O selection signal SEL1. That is, a signal may be transmitted between the first lower semiconductor IP core 110_1 and the first I/O circuit 130 along first paths PATH 1 shown by one-point dashed lines in FIG. 7.

Since the first lower semiconductor IP core 110_1 is an I/O target, a signal, such as a test input signal ti generated by the test equipment 20 in FIG. 1, received by the first I/O circuit 130 of the first chip 100 may be provided to the first lower semiconductor IP core 110_1. Likewise, a signal output by the first lower semiconductor IP core 110_1, such as a test result signal tr including a result corresponding to the test input signal ti in FIG. 1, may be provided to the test equipment 20 through the first I/O circuit 130.

Since the first chip 100 operates in the first test mode, the test enable circuit 150 may generate a test enable signal TEN and a buffer enable signal BEN. A logic level of the buffer enable signal BEN may be a high level. The first test buffer 152 may provide the test enable signal TEN to the first receiver 161, and the second test buffer 153 may provide the test enable signal TEN to the second receiver 162.

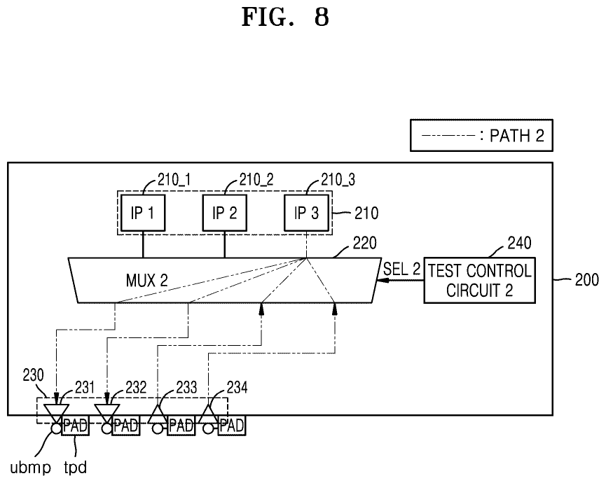

FIG. 8 illustrates a first chip 200 according to an embodiment. FIG. 8 may be described with reference to FIGS. 1 to 4, and redundant descriptions may be omitted.

Specifically, FIG. 8 shows a case in which the second chip 200 operates in the first test mode. The fact that the second chip 200 operates in the first test mode may be premised that the first chip 100 and the second chip 200 are not connected with each other. In FIG. 8, it may be assumed for ease of explanation, without limitation thereto, that the test target of the test equipment 20 is the third upper semiconductor IP core 210_3.

The test equipment 20 may control the second test control circuit 240 so that the second chip 200 operates in the first test mode.

The test equipment 20 may control the second test control circuit 240 so that the second test control circuit 240 generates a second I/O selection signal SEL2 including information corresponding to the third upper semiconductor IP core 210_3.

The second multiplexing circuit 220 may select the third upper semiconductor IP core 210_3 as an I/O target in response to the second I/O selection signal SEL2. That is, a signal may be transmitted between the third lower semiconductor IP core 210_3 and the second I/O circuit 230 along second paths PATH 2 shown by one-point dashed lines in FIG. 8.

Since the third lower semiconductor IP core 210_3 is an I/O target, a signal, such as a test input signal ti generated by the test equipment 20 in FIG. 1, received by the second I/O circuit 230 of the second chip 200 may be provided to the third lower semiconductor IP core 210_3. Likewise, a signal output by the third lower semiconductor IP core 210_3, such as a test result signal tr including a result corresponding to the test input signal ti in FIG. 1, may be provided to the test equipment 20 through the second I/O circuit 230.

In an embodiment, the second chip 200 may include test pads tpd. Since the size of the second bumps ubmp is smaller than the size of the first bumps bmp in FIG. 3, the second bumps ubmp may be damaged when the second bumps ubmp are directly connected to the test equipment 20. Therefore, each of the second bumps ubmp may be electrically connected to the test pads tpd, and a signal may be transmitted between the second chip 200 and the test equipment 20 through the test pads tpd. Accordingly, even if the second chip 200 is tested with the test equipment 20, an issue in which the second bumps ubmp are damaged may be prevented.

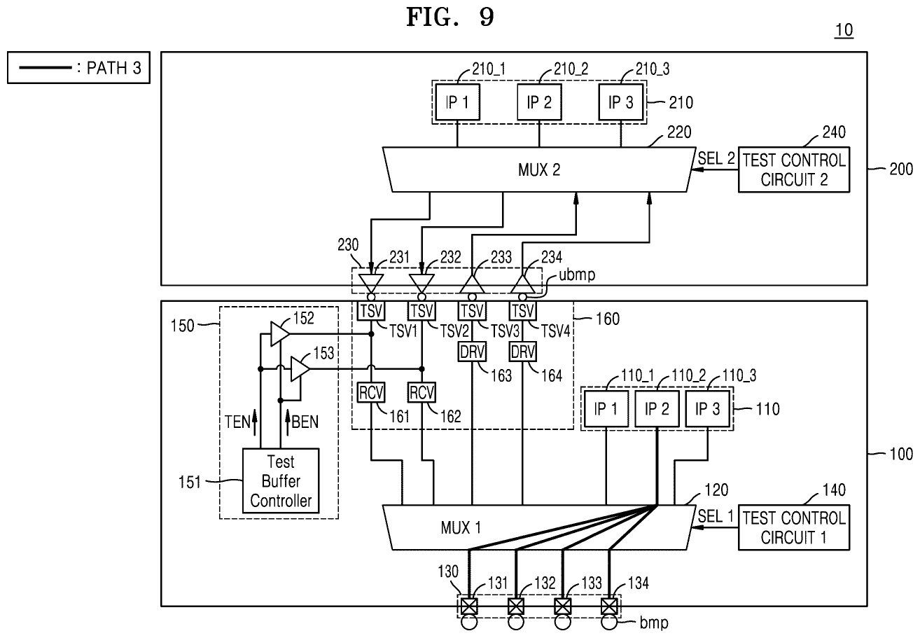

FIG. 9 illustrates an integrated circuit 10 according to an embodiment. FIG. 9 may be described with reference to FIGS. 1 to 4, and redundant descriptions may be omitted.

FIG. 9 represents a case in which the integrated circuit 10 operates in the second test mode. Specifically, FIG. 9 shows a case in which the first chip 100 operates in the second test mode. The fact that the integrated circuit 10 operates in the second test mode means that, with the first chip 100 and the second chip 200 connected with each other, the integrated circuit 10 performs a test operation on the first chip 100 or the second chip 200 under the control of the test equipment 20. In the present disclosure, when the integrated circuit 10 operates in the second test mode, and when a semiconductor IP core selected from among the plurality of first semiconductor IP cores 110 included in the first chip 100 is a test target, the first chip 100 may be referred to as operating in the second test mode. Likewise, when the integrated circuit 10 operates in the second test mode, and when a semiconductor IP core selected from among the plurality of first semiconductor IP cores 210 included in the second chip 200 is a test target, the second chip 200 may be referred to as operating in the second test mode.

In FIG. 9, it may be assumed for ease of explanation, without limitation thereto, that a test target of the test equipment 20 is a second lower semiconductor IP core 110_2 of the first chip 100. The test equipment 20 may control the first test control circuit 140 and the test enable circuit 150 so that the first chip 100 operates in the second test mode.

The test equipment 20 may control the first test control circuit 140 so that the first test control circuit 140 generates a first I/O selection signal SEL1 including information corresponding to the second lower semiconductor IP core 110_2. The second I/O selection signal SEL2 need not be generated. In some embodiments, the second I/O selection signal SEL2 may include information corresponding to any one semiconductor IP core arbitrarily selected from among a plurality of second semiconductor IP cores 210.

The test equipment 20 may control the test enable circuit 150 so that the test enable circuit 150 generates a buffer enable signal BEN whose logic level is low. That is, the first test buffer 152 and the second test buffer 153 may operate in a high-impedance state.

The test equipment 20 may control the first test control circuit 140 so that the first test control circuit 140 generates a first I/O selection signal SEL1 including information corresponding to the second lower semiconductor IP core 110_2.

The first multiplexing circuit 120 may select the second lower semiconductor IP core 110_2 as an I/O target in response to the first I/O selection signal SEL1. That is, a signal may be transmitted between the second lower semiconductor IP core 110_2 and the first I/O circuit 130 along third paths PATH 3 shown by thick solid lines in FIG. 9.

Since the second lower semiconductor IP core 110_2 is an I/O target, a signal, such as a test input signal ti generated by the test equipment 20 in FIG. 1, received by the first I/O circuit 130 of the first chip 100 may be provided to the second lower semiconductor IP core 110_2. Likewise, a signal output by the second lower semiconductor IP core 110_2, such as a test result signal tr including a result corresponding to the test input signal ti in FIG. 1, may be provided to the test equipment 20 through the first I/O circuit 130.

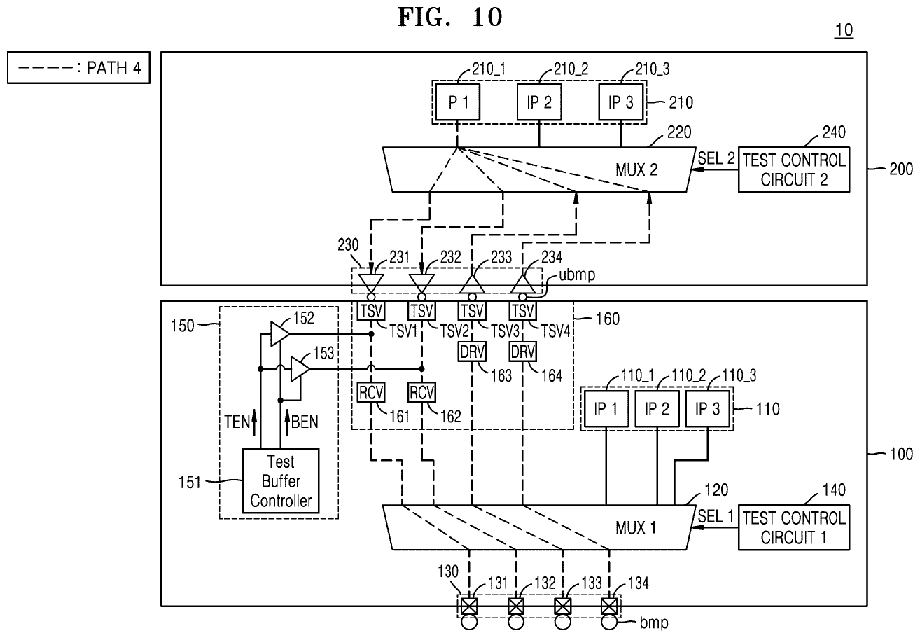

FIG. 10 illustrates an integrated circuit 10 according to an embodiment. FIG. 10 may be described with reference to FIGS. 1 to 4, and 9, and redundant descriptions may be omitted.

FIG. 10 represents a case in which the integrated circuit 10 operates in the second test mode. Specifically, FIG. 10 shows a case in which the second chip 200 operates in the second test mode.

In FIG. 10, it may be assumed for ease of explanation, without limitation thereto, that a test target of the test equipment 20 is a first upper semiconductor IP core 210_1 of the second chip 200. The test equipment 20 may allow the first chip 100 and the second chip 200 to operate in the second test mode. The test equipment 20 may control the first test control circuit 140 and the test enable circuit 150 so that the first chip 100 operates in the second test mode.

The test equipment 20 may control the first test control circuit 140 so that the first test control circuit 140 generates a first I/O selection signal SEL1 including information corresponding to the first upper semiconductor IP core 210_1.

The test equipment 20 may control the test enable circuit 150 so that the test enable circuit 150 generates a buffer enable signal BEN whose logic level is low. That is, the first test buffer 152 and the second test buffer 153 may operate in a high-impedance state, and in this case, the test enable signal TEN need not be provided to the chip connection circuit 160.

The test equipment 20 may control the first test control circuit 140 so that the first test control circuit 140 generates a first I/O selection signal SEL1 including information corresponding to the chip connection circuit 160.

The test equipment 20 may control the second test control circuit 240 so that the second test control circuit 240 generates a second I/O selection signal SEL2 including information corresponding to the first upper semiconductor IP core 210_1.

The first multiplexing circuit 120 may select the chip connection circuit 160 as a first I/O target in response to the first I/O selection signal SEL1. The second multiplexing circuit 220 may select the second upper semiconductor IP core 210_2 as a second I/O target in response to the second I/O selection signal SEL2. That is, a signal may be transmitted between the first upper semiconductor IP core 210_1 and the first I/O circuit 130 along fourth paths PATH 4 shown by thick solid lines in FIG. 10.

Specifically, in the first multiplexing circuit 120, since the chip connection circuit 160 is the first I/O target, a signal received by the first I/O circuit 130 of the first chip 100, such as a test input signal ti generated by the test equipment 20 in FIG. 1, may be provided to the chip connection circuit 160. Likewise, a signal output by the chip connection circuit 160, such as a test result signal tr including a result corresponding to the test input signal ti in FIG. 1, may be provided to the test equipment 20 through the first I/O circuit 130.

Specifically, in the second multiplexing circuit 220, since the first upper semiconductor IP core 210_1 is the second I/O target, a signal received by the second I/O circuit 230 of the second chip 200 may be provided to the first upper semiconductor IP core 210_1. Likewise, the signal output by the first upper semiconductor IP core 210_1 may be provided to the test equipment 20 through the second I/O circuit 230.

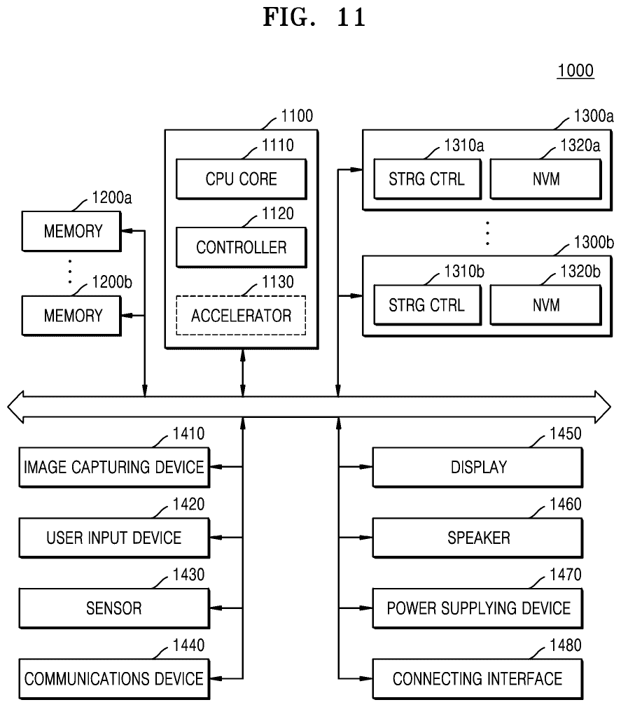

FIG. 11 illustrates a system 1000 including an integrated circuit according to an embodiment.

The system 1000 of FIG. 11 may include a mobile system, such as a mobile phone, a smartphone, a tablet personal computer (PC), a wearable device, a healthcare device, or an Internet of Things (IoT) device. However, the system 1000 of FIG. 11 is not necessarily limited to a mobile system and may include a PC, laptop computer, server, media player, or automotive device such as a navigation.

Referring to FIG. 11, the system 1000 may include a main processor 1100, memories 1200a and 1200b, and storage devices 1300a and 1300b. In addition, the system 1000 may include one or more of an image capturing device 1410, a user input device 1420, a sensor 1430, a communications device 1440, a display 1450, a speaker 1460, a power supplying device 1470, and a connecting interface 1480. In this case, each of the components constituting the system 1000 of FIG. 11, that is, the main processor 1100, the memories 1200a and 1200b, the storage devices 1300a and 1300b, the image capturing device 1410, the user input device 1420, the sensor 1430, the communications device 1440, the display 1450, the speaker 1460, the power supplying device 1470, and the connection interface 1480, may be implemented using embodiments described supra with reference to FIGS. 1 to 10.

The main processor 1100 may control the overall operation of the system 1000, more specifically, the operation of other components constituting the system 1000. The main processor 1100 may be implemented as a general-purpose processor, a dedicated processor, an application processor, or the like.

The main processor 1100 may include one or more CPU cores 1110 and may further include a controller 1120 for controlling the memories 1200a and 1200b and/or the storage devices 1300a and 1300b. According to an embodiment, the main processor 1100 may further include an accelerator 1130, which is a dedicated circuit for high-speed data operations such as an artificial intelligence (AI) data operation, without limitation. The accelerator 1130 may include a graphics processing unit (GPU), a neural processing unit (NPU), and/or a data processing unit (DPU) and may be implemented as a separate chip physically independent of other components of the main processor 1100.

The memories 1200a and 1200b may be used as main memory devices of the system 1000 and may include volatile memories, such as SRAM and/or DRAM, but may also include nonvolatile memories, such as flash memory, PRAM and/or RRAM. The memories 1200a and 1200b may be implemented in the same package as the main processor 1100.

The storage devices 1300a and 1300b may function as nonvolatile storage devices that store data regardless of whether power is supplied to the storage devices, and may have a relatively large storage capacity compared to the memories 1200a and 1200b. The storage devices 1300a and 1300b may include storage controllers 1310a and 1310b and nonvolatile memories (NVM) 1320a and 1320b that store data under control of the storage controllers 1310a and 1310b. The nonvolatile memories 1320a and 1320b may include flash memory having a 2-dimensional (2D) structure or a 3-dimensional (3D) Vertical NAND (V-NAND) structure but may include other types of nonvolatile memories such as PRAM and/or RRAM.

The storage devices 1300a and 1300b may be included in the system 1000 by being physically separate from the main processor 1100, or may be implemented in the same package as the main processor 1100. In addition, the storage devices 1300a and 1300b may be detachably combined with other components of the system 1000 through an interface such as the connecting interface 1480, which is described in greater detail infra, by having a form such as a solid state device (SSD) or a memory card. The storage devices 1300a and 1300b may be devices to which standard protocols such as UFS, eMMC, or nonvolatile memory express (NVMe) are applied, but are not necessarily limited thereto.

The image capturing device 1410 may capture a still image or a moving image and may include a camera, a camcorder, and/or a webcam.

The user input device 1420 may receive various types of data input from a user of the system 1000; and may include a touch pad, a keypad, a keyboard, a mouse, and/or a microphone.

The sensor 1430 may detect various types of physical quantities that may be obtained from outside of the system 1000 and convert the detected physical quantities into electrical signals. The sensor 1430 may include a temperature sensor, a pressure sensor, an illuminance sensor, a position sensor, an acceleration sensor, a biosensor, and/or a gyroscope sensor.

The communications device 1440 may transmit and receive signals to and from other devices outside the system 1000 according to various communications protocols. The communications device 1440 may be implemented by including an antenna, a transceiver, and/or a modem.

The display 1450 and the speaker 1460 may function as output devices that output visual information and auditory information to users of the system 1000, respectively.

The power supplying device 1470 may appropriately convert power supplied from a battery embedded in the system 1000 and/or an external power source into the system 1000 and supply the power to each component of the system 1000.

The connecting interface 1480 may provide a connection between the system 1000 and an external device connected to the system 1000 and be capable of transmitting and receiving data to and from the system 1000. The connecting interface 1480 may be implemented using a variety of interface methods such as Advanced Technology Attachment (ATA), Serial ATA (SATA), External SATA (e-SATA), Small Computer Small Shop Interface (SCSI), Serial Attached SCSI (SAS), Peripheral Component Interconnect (PCI), PCI express (PCIe), NVMe, IEEE 1394, universal serial bus (USB), Secure Digital (SD) card interface, MMC, eUFS, Compact Flash (CF) card interface, and the like.

While the inventive concept has been particularly shown and described with reference to embodiments thereof, it will be understood by those of ordinary skill in the pertinent art that various changes in form and details may be made therein without departing from the scope and spirit of the following claims.

What is claimed is:

1. An integrated circuit comprising:
a plurality of first semiconductor intellectual property (IP) cores;
a chip connection circuit including a first through silicon via, a second through silicon via, a receiver electrically connected to the first through silicon via, and a driver electrically connected to the second through silicon via;
a multiplexing circuit configured to select any one of the plurality of first semiconductor IP cores or the chip connection circuit as an input/output (I/O) target based on an I/O target selection signal;
a test enable circuit configured to provide a test enable signal to the chip connection circuit, based on a test mode of the integrated circuit; and
a test control circuit configured to provide the I/O target selection signal to the multiplexing circuit.

2. The integrated circuit of claim 1, wherein the receiver is configured to provide the multiplexing circuit with a signal received from the outside through the first through silicon via, and the driver is configured to output a signal output from the multiplexing circuit to the outside through the second through silicon via.

3. The integrated circuit of claim 1, wherein the test enable circuit further comprises:
a test buffer controller configured to generate a buffer enable signal and the test enable signal; and
a test buffer configured to receive the test enable signal from the test buffer controller and provide the test enable signal to the receiver in response to the buffer enable signal,
wherein the test enable signal includes a first value.

4. The integrated circuit of claim 3,
wherein the test buffer controller is configured to generate the buffer enable signal and the test enable signal when the integrated circuit operates in a first test mode, and
wherein the test buffer is configured to operate in a high-impedance state when the integrated circuit operates in a second test mode or in a normal mode.

5. The integrated circuit of claim 1, wherein:
the plurality of first semiconductor IP cores comprise a test target semiconductor, and
the I/O target selection signal comprises a value for setting the test target semiconductor as the I/O target.

6. The integrated circuit of claim 1, further comprising an I/O circuit configured to electrically connect an external device with the multiplexing circuit, transmit a signal from the external device to the multiplexing circuit, and transmit a signal from the multiplexing circuit to the external device.

7. The integrated circuit of claim 6, wherein a voltage of the signal provided by the multiplexing circuit to the I/O circuit is less than a voltage of the signal provided by the I/O circuit to the external device.

8. The integrated circuit of claim 6, wherein the multiplexing circuit is configured to provide a signal from the I/O target to the I/O circuit, and provide a signal received from the I/O circuit to the I/O target.

9. An integrated circuit comprising a first chip and a second chip,
wherein the first chip comprises:
a plurality of first semiconductor intellectual property (IP) cores;
a chip connection circuit including a first through silicon via and a second through silicon via electrically connected to the second chip;
a first multiplexing circuit configured to select any one of the plurality of first semiconductor IP cores or the chip connection circuit as a first input/output (I/O) target based on a first I/O target selection signal;
a test enable circuit configured to provide a test enable signal to the chip connection circuit, based on a test mode of the integrated circuit; and
a first test control circuit configured to provide the first I/O target selection signal to the first multiplexing circuit, and
wherein the second chip is arranged above the first chip and comprises:
a plurality of second semiconductor IP cores;
a second multiplexing circuit configured to select any one of the plurality of second semiconductor IP cores as a second I/O target, based on a second I/O target selection signal; and
a test control circuit configured to provide the second I/O target selection signal to the second multiplexing circuit.

10. The integrated circuit of claim 9, wherein the chip connection circuit further comprises:
a receiver electrically connected to the first through silicon via and configured to provide a signal received from the second chip through the first through silicon via to the first multiplexing circuit; and
a driver electrically connected to the second through silicon via and configured to provide a signal output from the first multiplexing circuit to the second chip through the second through silicon via.

11. The integrated circuit of claim 10, wherein the first chip further comprises:
a first power line to which a first power having a first voltage is applied from an external device;
a second power line to which a second power having a second voltage is applied from the external device;
a first level shift circuit electrically connected to the first power line and the second power line, and configured to shift a voltage of the signal received from the receiver to the first voltage, and provide the signal received from the receiver to the first multiplexing circuit; and
a second level shift circuit electrically connected to the first power line and the second power line, and configured to shift a voltage of the signal received from the first multiplexing circuit to the second voltage, and provide the signal received from the first multiplexing circuit to the driver.

12. The integrated circuit of claim 9, wherein the test enable circuit further comprises:
a test buffer controller configured to generate a buffer enable signal and the test enable signal based on a test mode of the integrated circuit; and
a test buffer configured to receive the test enable signal from the test buffer controller and provide the test enable signal to the receiver in response to the buffer enable signal.

13. The integrated circuit of claim 12, wherein:
the test buffer controller is configured to, when the integrated circuit operates in a first test mode, generate the buffer enable signal and the test enable signal, and
the test buffer is configured to, when the integrated circuit operates in a second test mode or in a normal mode, operate in a high-impedance state.

14. The integrated circuit of claim 9, wherein the first chip further comprises a first I/O circuit configured to electrically connect an external device with the first multiplexing circuit, transmit signals from the external device to the first multiplexing circuit, and transmit signals from the first multiplexing circuit to the external device.

15. The integrated circuit of claim 9, wherein the second chip further comprises a second I/O circuit configured to electrically connect the first chip with the second multiplexing circuit, transmit signals from the first chip to the second multiplexing circuit, and transmit signals from the second multiplexing circuit to the first chip.

16. The integrated circuit of claim 9, wherein the first I/O target selection signal includes a value for setting a test target semiconductor IP core selected from among the plurality of first semiconductor IP cores as the first I/O target when the integrated circuit operates in a test mode for testing the first chip.

17. The integrated circuit of claim 9, wherein the first I/O target selection signal includes a value for setting the chip connection circuit as the first I/O target, and the second I/O target selection signal includes a value for setting a test target semiconductor IP core selected from among the plurality of second semiconductor IP cores as the second I/O target, when the integrated circuit operates in a test mode for testing the second chip.

18. A test system comprising:
an integrated circuit; and
test equipment configured to test the integrated circuit,
wherein the integrated circuit comprises:
a plurality of first semiconductor intellectual property (IP) cores;
a chip connection circuit including a first through silicon via, a second through silicon via, a receiver electrically connected to the first through silicon via, and a driver electrically connected to the second through silicon via;
a first multiplexing circuit configured to select any one of the plurality of first semiconductor IP cores or the chip connection circuit as a first input/output (I/O) target based on a first I/O target selection signal;
a test enable circuit configured to provide a test enable signal to the chip connection circuit, based on a test mode of the integrated circuit;
a first test control circuit configured to provide the first I/O target selection signal to the first multiplexing circuit; and
a first chip including a first I/O circuit configured to electrically connect the test equipment and the first multiplexing circuit, transmit signals from the test equipment to the first multiplexing circuit, and transmit signals from the first multiplexing circuit to the test equipment.

19. The test system of claim 18,
wherein the test enable circuit further comprises:
a test buffer controller configured to generate a buffer enable signal and the test enable signal; and
a test buffer configured to receive the test enable signal from the test buffer controller and provide the test enable signal to the receiver in response to the buffer enable signal,
wherein the test enable signal includes a first value.

20. The test system of claim 18, wherein the integrated circuit further comprises a second chip arranged above the first chip, the second chip comprising:
a plurality of second semiconductor IP cores;
a second multiplexing circuit configured to select any one of the plurality of second semiconductor IP cores as a second I/O target based on a second I/O target selection signal;
a second test control circuit configured to provide the second I/O target selection signal to the second multiplexing circuit; and
a second I/O circuit configured to electrically connect the first chip with the second multiplexing circuit, transmit signals from the first chip to the second multiplexing circuit, and transmit signals from the second multiplexing circuit to the first chip.
